(19) United States
(12) Patent Application Publication
(10) Pub. No.: US 2025/0012835 A1
(43) Pub. Date: Jan. 9, 2025

(54) MEASUREMENT OF INSULATION RESISTANCE OF AN ELECTRICAL INSULATOR

(71) Applicant: Megger Instruments Ltd, Dover (GB)

(72) Inventor: Stanislaw ZUREK, Dover (GB)

(21) Appl. No.: 18/892,083

(22) Filed: Sep. 20, 2024

Related U.S. Application Data
(63) Continuation of application No. PCT/GB2023/050719, filed on Mar. 21, 2023.

(30) Foreign Application Priority Data
Mar. 23, 2022 (GB) 2204058.8

(51) Int. Cl. G01R 27/02

(52) U.S. Cl. CPC G01R 27/025

(57) ABSTRACT

Measurement apparatus performs a measurement of insulation resistance of an electrical insulator by applying a voltage to the electrical insulator, increasing the voltage with time, and measuring the resulting current through the electrical insulator. An output from an electrical circuit for measuring current through the electrical insulator is sampled by iteratively performing steps of producing samples representing currents measured when the voltage applied to the electrical insulator is increased by successive increments. For each iteration, a threshold is determined for the current measured in the iteration by processing at least one sample measured for the respective iteration and samples measured for a plurality of previous iterations. Increasing the voltage applied to the electrical insulator is stopped in response to the current measured in the iteration exceeding the determined threshold.

### CROSS-REFERENCE TO RELATED APPLICATIONS

This application is a continuation under 35 U.S.C. § 120 of International Application No. PCT/GB2023/050719, filed Mar. 21, 2023, which claims priority to GB Application No. GB 2204058.8, filed Mar. 23, 2022, under 35 U.S.C. § 119(a). Each of the above-referenced patent applications is incorporated by reference in its entirety.

### TECHNICAL FIELD

The present invention relates generally to an improved method of operation for a measurement apparatus and to an improved measurement apparatus for measuring insulation resistance of an electrical insulator.

### BACKGROUND

Measurements of electrical resistance of an electrical insulator, for example the insulation of windings of an electric motor, are typically performed periodically, to check the condition of the insulator, which may degrade with time. The measurement may be performed by applying an increasing voltage, typically increasing as a step function or as a ramp and measuring the resulting current flowing in the insulator. Tests may be performed according to IEEE95-2002 Recommended Practice of Insulation Testing of AC Electric Machinery, and as described in “Pruebas Eléctricas Estáticas Recomendadas en Sistemas de Aislamiento de Máquinas Eléctricas Rotativas para un Mantenimiento Predictivo Eficaz” Static Article Luis Beltran PDF|PDF (scribd.com) (Recommended Static Electrical Tests in Insulation Systems of Rotating Electrical Machines for Effective Predictive Maintenance} by Luis Beltran. If the applied voltage is increased to a point where the insulator breaks down, then the insulator may be damaged, so it is desired to stop the test before a breakdown voltage is reached. An operator may detect that the applied voltage is approaching the breakdown voltage by observing that a characteristic of current versus voltage deviates from a smooth curve. However, this requires judgement on the part of the operator, and the shapes and absolute values of current versus voltage characteristics vary greatly according to the type of insulator and its condition. Furthermore, especially for insulators having a high resistance, or if the measurements are performed in a noisy environment, the values of current to be measured may be very small and the measurements may be noisy, leading to an irregular characteristic, so that it is difficult to judge when a characteristic of current versus voltage deviates from a smooth curve. A limit may be set to the proportion that a current may increase from one value of applied voltage to the next. For example, the test may be stopped if the current increases by a factor of two when the voltage is increased. However, this approach is unreliable due to the high degree of variation between typical characteristics for different insulators. It would be desirable to have a measurement apparatus using a measurement technique that is automatically adapted to measure different types of insulator having widely differing characteristics and to operate using potentially noisy measurements.

### SUMMARY

In accordance with a first aspect, there is provided a method of operation of a measurement apparatus for performing a measurement of insulation resistance of an electrical insulator by applying a voltage to the electrical insulator, increasing the voltage with time, and measuring the resulting current through the electrical insulator for a plurality of applied voltages, the method comprising:
sampling an output from an electrical circuit for measuring current through the electrical insulator to produce at least one sample, the at least one sample representing a current measured when there is a first voltage applied to the electrical insulator;
iteratively performing steps of sampling the output from the electrical circuit to produce one or more further samples, the one or more further samples representing respective currents measured when the voltage applied to the electrical insulator is increased by successive increments;
for each iteration, determining a threshold of a first category for the at least one sample representing current measured in the iteration by processing at least one sample measured for the respective iteration and samples measured for a plurality of previous iterations; and
stopping increasing the voltage applied to the electrical insulator in response to the measured at least one sample representing current exceeding the determined threshold of the first category for the respective iteration.

This method allows the measurement apparatus to be operated automatically to measure different types of insulator having widely differing characteristics with a reduced risk of causing breakdown of the insulator.

In an example, the method comprises determining the threshold of the first category for the at least one sample representing current measured in each iteration by a process comprising, for each iteration, fitting a function which relates current to voltage to at least one sample measured for the respective iteration and for samples measured for a plurality of previous iterations.

This method allows a threshold for stopping the measurement to be automatically adapted according to the characteristics of the insulator being measured.

In an example, said fitting comprises calculating a mean gradient of the function for the current iteration and previous iterations, in which, dependent on a respective gradient being negative, the respective gradient is set to zero for the purpose of calculating the mean gradient.

This method allows for a reliable determination of a threshold for stopping the measurement for example for insulators having a high resistance, for which the values of current to be measured may be very small and the measurements may be noisy, leading to an irregular characteristic of voltage versus current.

In an example, said fitting comprises calculating a mean intercept of the function for the current iteration and previous iterations, in which, dependent on a respective intercept being negative, the respective intercept is set to zero for the purpose of calculating the mean intercept.

This method allows for a reliable determination of a threshold for stopping the measurement for cases where the measurements may be noisy, leading to an irregular characteristic of voltage versus current.

In an example, the method comprises calculating the threshold of a first category for the at least one sample representing current measured in the iteration by a process comprising determining a value of the function for the value of voltage applied for the iteration in question and multiplying the determined value of the function by a first predetermined factor.

This allows the threshold to be determined reliably and automatically using a pre-determined factor that is applicable to a variety of different insulation types.

In an example, the method comprises calculating the threshold of a first category for the at least one sample representing current measured in the iteration by a process comprising taking the determined value of the function multiplied by the predetermined factor and adding a factor related to a noise level in the measured data.

In an example, the factor related to a noise level in the measured data is generated by a process comprising taking a standard deviation or variance of the difference between measured data and the function, in which more recent data is de-weighted in comparison to older data.

This method allows a reliable estimate of noise to be made that is not unduly influenced by the effects of increase in current due to the approach of the breakdown voltage.

In an example, the method comprises generating an electronic display showing measured samples of current as a function of applied voltage and a function representing a threshold of the first category as a function of applied voltage.

This method allows an intuitive display to be provided to a user to show the progress of the test and to indicate whether the test is approaching breakdown voltage.

In an example, the method comprises determining a threshold of a second category for each iteration by processing at least one sample measured for the respective iteration and samples measured for a plurality of previous iterations; and
generating a second electronic signal indicating that there is a risk of insulation failure in response to the measured at least one sample representing current exceeding the determined threshold of the second category for the respective iteration.

This method allows a warning of a risk of insulation failure to be provided automatically before the measurement is stopped.

In example, the method comprises generating an electronic display showing measured samples of current as a function of applied voltage and the threshold of the second category as a function of applied voltage.

This method allows an intuitive display to be provided to a user to show the progress of the test and to indicate a degree to which the test is approaching breakdown voltage.

In an example, the method comprises:
determining a threshold of a third category for each iteration by processing at least one sample measured for the respective iteration and samples measured for a plurality of previous iterations; and
generating a third electronic signal indicating that there is a risk of insulation failure in response to the measured at least one sample representing current exceeding the determined threshold of the third category for the respective iteration, wherein the third electronic signal indicates a higher risk of insulation failure than does the second electronic signal.

This method allows a more finely graduated indication to the user of the level of risk of insulation breakdown.

In an example, the method comprises stopping applying voltage to the electrical insulator in response to the measured at least one sample representing current exceeding the determined threshold of the first category for the respective iteration.

This method allows risk of insulation breakdown to be reduced.

In an example, the method comprises generating an electronic signal indicating that the measurement has stopped in response to the measured at least one sample representing current exceeding the determined threshold of the first category for the respective iteration.

This method provides an indication to a user of the state of the measurement.

In accordance with a second aspect of the invention, there is provided measurement apparatus for performing a measurement of insulation resistance of an electrical insulator by applying a voltage to the electrical insulator, increasing the voltage with time, and measuring the resulting current through the electrical insulator for a plurality of applied voltages, the apparatus comprising:
an electrical circuit for applying a voltage to the electrical insulator;
an electrical circuit for measuring current through the electrical insulator; and
at least one processor configured to cause the measurement apparatus to:
sample an output from an electrical circuit for measuring current through the electrical insulator to produce at least one sample, the at least one sample representing a current measured when there is a first voltage applied to the electrical insulator;
iteratively perform steps of sampling the output from the electrical circuit to produce one or more further samples, the one or more further samples representing respective currents measured when the voltage applied to the electrical insulator is increased by successive increments;
for each iteration, determine a threshold of a first category for the at least one sample representing current measured in the iteration by processing at least one sample measured for the respective iteration and samples measured for a plurality of previous iterations; and
stop increasing the voltage applied to the electrical insulator in response to the measured at least one sample representing current exceeding the determined threshold of the first category for the respective iteration.

In an example, the at least one processor is configured to cause the measurement apparatus to perform examples of the method as already mentioned.

In an example, the measurement apparatus comprises a meter and a device external to the meter comprising a processor and a display, wherein the meter comprises the electrical circuit for applying a voltage to the electrical insulator, the electrical circuit for measuring current through the electrical insulator and an electrical circuit for communicating with said device.

This provides a convenient display for the measurement results and indications.

In accordance with a third aspect of the invention, there is provided a computer-readable storage medium holding instructions for causing one or more processors to cause measurement apparatus for performing a measurement of insulation resistance of an electrical insulator to:
receive at least one sample, the at least one sample representing a current measured when there is a first voltage applied to the electrical insulator;
iteratively perform steps of receiving one or more further samples, the one or more further samples representing respective currents measured when the voltage applied to the electrical insulator is increased by successive increments;
for each iteration, determine a threshold of a first category for the at least one sample representing current measured in the iteration by processing at least one sample measured for the respective iteration and samples measured for a plurality of previous iterations; and
cause the measurement apparatus to stop increasing the voltage applied to the electrical insulator in response to the measured at least one sample representing current exceeding the determined threshold of the first category for the respective iteration.

Further features and advantages of the will be apparent from the following description of exemplary embodiments, which are given by way of example only.

### BRIEF DESCRIPTION OF THE DRAWINGS

FIG. 1 is a schematic diagram illustrating measurement apparatus for performing a measurement of insulation resistance of an electrical insulator;

FIG. 2 is a graph illustrating, as a function of time, a stepped increase in voltage applied to an insulator by the measurement apparatus, the resulting current as a function of time and end-of-step current measurements sampled by the measurement apparatus;

FIG. 3 is a graph illustrating end-of-step current measurement samples as a function of applied voltage;

FIG. 4 is a graph illustrating samples of measured current as a function of applied voltage and thresholds of a first, second and third category for a first set of measurements;

FIG. 5 is a graph illustrating samples of measured current as a function of applied voltage and thresholds of a first, second and third category for a second set of measurements;

FIG. 6 is a graph illustrating samples of measured current as a function of applied voltage and thresholds of a first, second and third category for a third set of measurements;

FIG. 7 is a graph illustrating samples of measured current as a function of applied voltage and thresholds of a first, second and third category for a fourth set of measurements, in which a sample exceeds the threshold of the first category;

FIG. 8 is a graph illustrating samples of measured current as a function of applied voltage and thresholds of a first, second and third category for a fifth set of measurements, illustrating fitting of a function to the measured samples;

FIG. 9 shows a time sequence of measurements illustrating how the thresholds of a first, second and third category are generated;

FIG. 10 illustrates generation of an estimate of noise by a process comprising weighting of samples; and

FIG. 11 is a flow chart illustrating a method of operation of the measurement apparatus.

### DETAILED DESCRIPTION

By way of example, embodiments will now be described in the context of a measurement apparatus capable of performing a measurement of insulation resistance of an electrical insulator by applying a voltage to the electrical insulator, increasing the voltage with time, and measuring the resulting current through the electrical insulator for a plurality of applied voltages, where the test apparatus is in the form of a dedicated test set designed for the purpose, but it will be understood that the measurement apparatus may take other forms, such a multi-function meter or other test equipment.

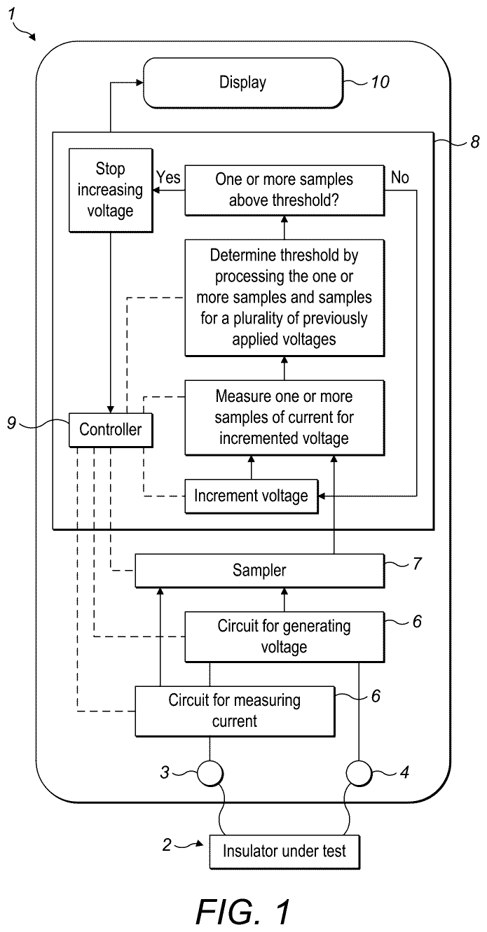

FIG. 1 shows an example of a measurement apparatus 1 for performing a measurement of insulation resistance of an electrical insulator by applying a voltage to the electrical insulator 2, increasing the voltage with time, and measuring the resulting current through the electrical insulator 2 for a plurality of applied voltages. As can be seen from FIG. 1, the insulator under test 2 is connected to the measurement apparatus 1 by at least two connection terminals 3, 4. The measurement apparatus comprises an electrical circuit 6 for generating a voltage and applying it to the electrical insulator 2, and an electrical circuit for measuring current through the electrical insulator. The insulation resistance of the insulator under test 2 is measured by applying a high DC (direct current) voltage, typically 1 kV or higher and measuring the resulting current, which is typically very small, typically of the order of microamps (uA). The insulation resistance, typically measured in MΩ, is calculated from the applied voltage and the measured current. In a Step Voltage (SV) test, the voltage is applied in increasing steps, with each step being effectively a shorter DC insulation resistance test. As an alternative, a Ramp Voltage (RV) test is an SV test in which the steps in voltage are very small, so that the voltage is increased effectively as a continuous ramp. During the test, the applied voltage is typically increased to be greater than the nominal operating voltage of the insulator under test, that is to say an overvoltage is applied, for example twice the nominal voltage+1 kV. If the insulation has deteriorated, the overvoltage test could lead to a breakdown of the insulation, for example a so-called “spark through”, and hence a failure of the whole insulation system of the insulator under test, for example a motor. This is undesirable, since a back-to-base repair may be required, before the system can be powered up again. The test equipment is configured to detect a risk of insulation breakdown automatically and to stop increasing the voltage, and/or to stop applying the voltage and to stop the test, generating an electronic signal indicating that the test has stopped. Two terminals are illustrated in FIG. 1, but some examples may be provided with an additional terminal which may be referred to as a guard terminal provided in the interests of increasing measurement accuracy. The guard terminal may be held at the same potential as one of the terminals but bypassing the internal ammeter of the meter. The guard terminal may be connected to the surface of the insulator under test, so that unwanted surface leakage current does not influence the result of the test.

The measurement apparatus of FIG. 1 comprises at least one processor 8, which includes the functionality of a controller 9. The processor may be implemented by hardware, software and/or firmware. Typically the processor or processors have memory in which machine executable code may be stored which causes the processor or processors to cause the measurement apparatus to carry out the insulation resistance measurement and to detect the risk of insulation breakdown automatically and to stop increasing the voltage. The one or more processors may be situated within a dedicated test set, as illustrated in FIG. 1, and/or one or more processors may be situated within a device remote from the dedicated test set, for example a user device such as a smart phone. The user device may have a data connection to a processor in the dedicated test set using a radio link, such as Bluetooth or WiFi. The one or more processors may be implemented by a remote data processing facility, such as cloud processing.

The at least one processor 8 is configured to cause the measurement apparatus to cause a sampler 7, typically comprising one or more analogue to digital converters, to sample an output from the electrical circuit 5 for measuring current through the electrical insulator to produce at least one sample. The at least one sample represents a current measured when there is a first voltage applied to the electrical insulator. The first voltage may be a step of voltage in a step voltage (SV) test. The processor cause the measurement apparatus to iteratively perform steps of sampling the output from the electrical circuit 5 to produce one or more further samples, the one or more further samples representing respective currents measured when the voltage applied to the electrical insulator 2 is increased by successive increments. For each iteration, a threshold of a first category is determined for the current measured in the iteration by processing at least one sample measured for the respective iteration and samples measured for a plurality of previous iterations. The one or more processors cause the measurement apparatus 1 to stop increasing the voltage applied to the electrical insulator in response to the measured at least one sample representing current exceeding the determined threshold of the first category for the respective iteration. This automatically protects the insulator from breakdown, without the need for user intervention of judgement. Generating the threshold by processing at least one sample for each iteration and also samples measured for previous iterations allows the threshold to be adjusted adaptively to the characteristics of the insulator under test as the test progresses. Insulators of different types may vary greatly in terms of the range of measured currents and the slope and shape of the current versus voltage characteristic.

The threshold of the first category is a threshold for stopping the increase in applied voltage and/or stopping the test, and crossing or reaching the threshold may cause the processor or processors to generate electronic signals causing a display 10 in the measurement apparatus 1 to indicate that the test has stopped, for example indicating “fail”. The display may be located in a dedicated test equipment and/or in a remote device such as a user device.

Other thresholds may also be determined for each iteration indicating degrees of risk of insulation breakdown, also generated by processing at least one sample measured for the respective iteration and samples measured for a plurality of previous iterations. For example, thresholds may be set to generate electronic signals causing a display 10 in the measurement apparatus 1 to indicating “caution”, “warning”, or “fail”.

In the example described, the samples representing current directly represent measured current, for example as measured in microamps. However, it will be understood that the samples representing current may be expressed in terms of insulation resistance, which is directly related to current. Therefore, throughout the description, references to current and measured current may be substituted with measurements of resistance derived from measurements of current. Each threshold may therefore be expressed as a threshold for measured resistance, which is equivalent to a threshold for current.

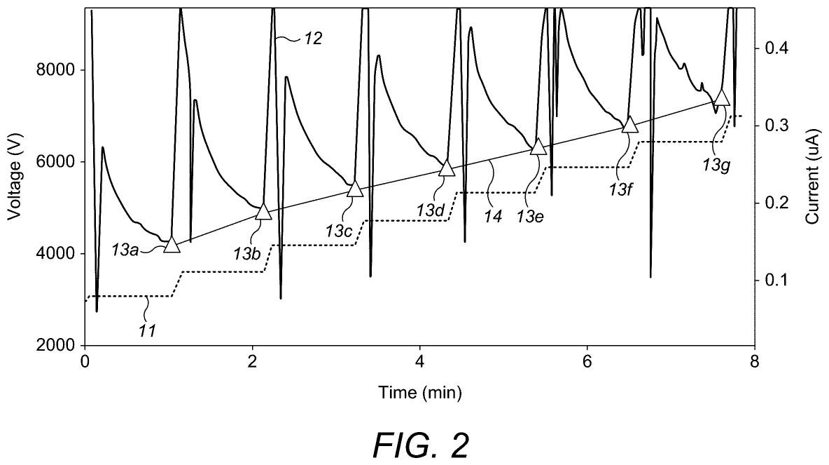

FIG. 2 is a graph illustrating, as a function of time, a stepped increase in voltage applied to an insulator by the measurement apparatus 1. The voltage is shown as line 11 and the value of voltage is indicated by the scale on the left-hand axis. The resulting current 12 is shown as a function of time and the value of current is indicated by the scale on the right-hand axis. In this example, it can be seen that the form of current against time has an approximately saw-tooth shape, in which the current increases rapidly at the beginning of each step of increased voltage, and then decays during the step. A sample of current is taken for each step, in this example towards the end of the step. The samples of current 13a-13g sampled by the measurement apparatus for each step are shown. The characteristic of current against time for the samples is shown in FIG. 2 as line 14.

As can be seen in FIG. 2, the applied voltage increased in steps. Each step is held for approximately 60 sec, and then the voltage is quickly ramped to the next step. Immediately after application of a voltage step the current increases rapidly due to the capacitive and absorption currents and then decays. If a step were infinitely long time the current would stabilise at a fixed leakage value for that step. In practice, just before the given step is finished the current is measured as samples of current.

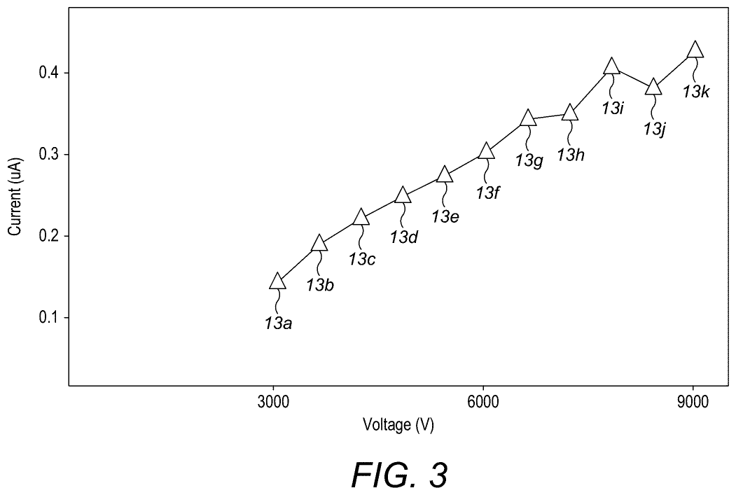

FIG. 3 shows the samples of current 13a-13g from FIG. 2 as a function of applied voltage, and also shows additional samples of current 13h-13k.

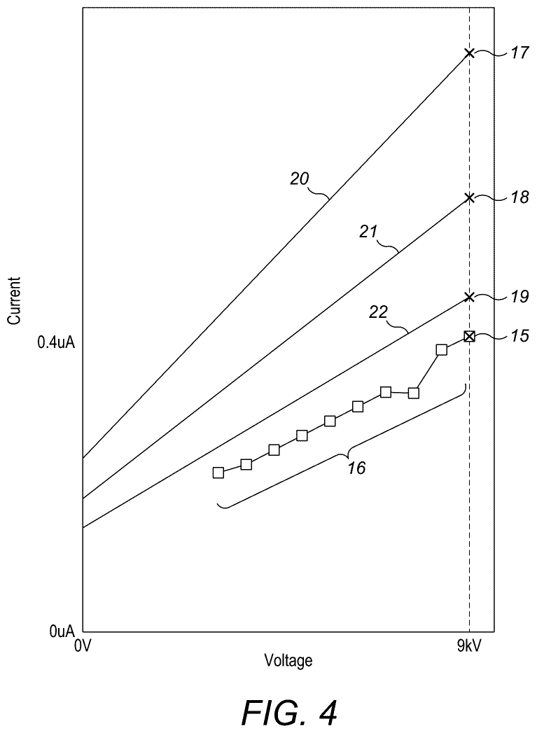

FIGS. 4-7 Figure are graphs illustrating samples of measured current as a function of applied voltage for respective sets of measurements on different insulators.

In FIG. 4, thresholds of a first category 17 (fail), second category 19 (caution) and third category 18 (warning) are shown for the last sample illustrated. The thresholds are determining by processing the last sample 15 and also the previous samples 16. Each threshold may be determined by a process comprising, for each iteration, fitting a function which relates current to voltage to at least one sample measured for the respective iteration and for samples measured for previous iterations. For the data in FIG. 4, the last sample taken did not pass any of the thresholds, so the measurement may be indicated as a “pass” for this voltage step.

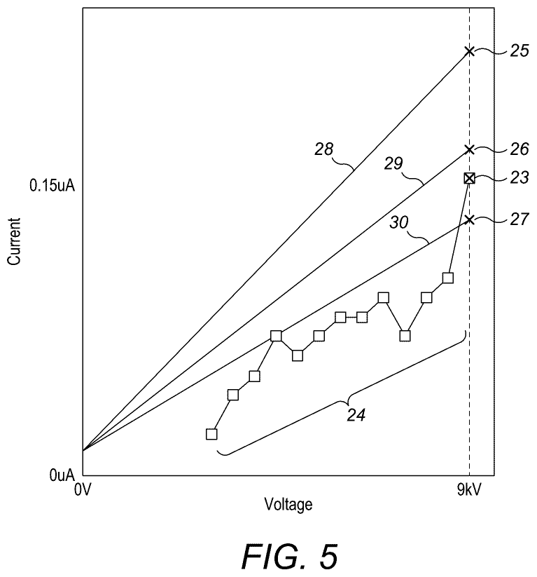

In FIG. 5, thresholds of a first category 25 (fail), second category 27 (caution) and third category 26 (warning) are shown for the last sample illustrated. The thresholds are determining by processing the last sample 23 and also the previous samples 24. For the data in FIG. 5, the last sample taken passed the threshold of the second category 27, so the display 10 may indicate as a “caution” for this voltage step.

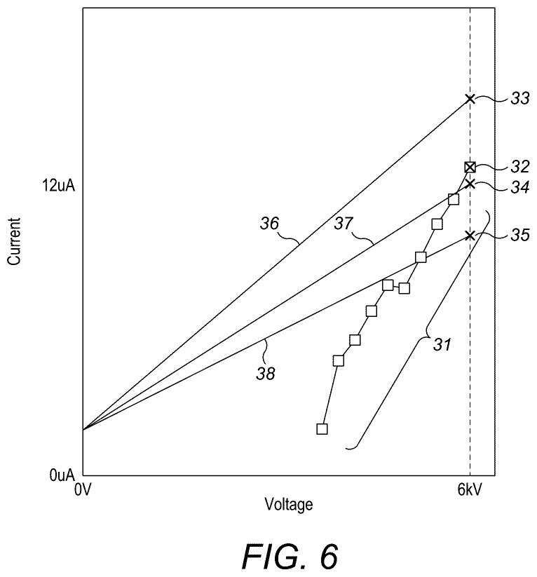

In FIG. 6, thresholds of a first category 33 (fail), second category 35 (caution) and third category 34 (warning) are shown for the last sample illustrated. The thresholds are determining by processing the last sample 32 and also the previous samples 31. For the data in FIG. 6, the last sample taken passed the threshold of the third category 34, so the display 10 may indicate as a “warning” for this voltage step.

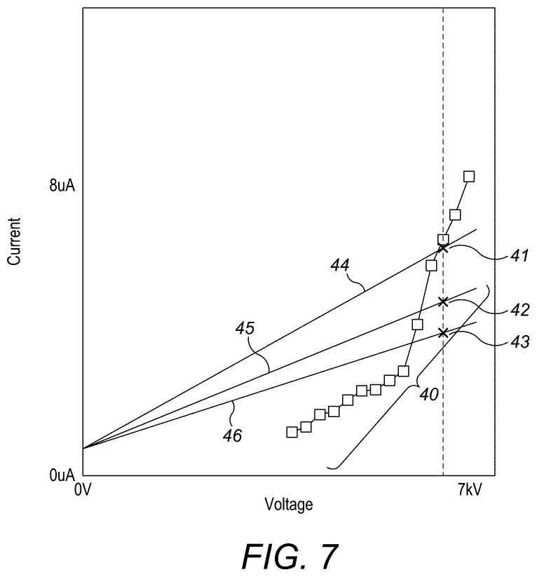

In FIG. 7, thresholds of a first category 41 (fail), second category 43 (caution) and third category 42 (warning) are shown for the third to last sample illustrated 39. The thresholds are determining by processing the sample 39 and also the previous samples 40. For the data in FIG. 7, the third to last sample taken 39 passed the threshold of the first category 41, so the display 10 may indicate as a “fail” for this voltage step. In the example of FIG. 7, the voltage is shown continuing to increase after the third to last sample 39 which exceeded the “fail” threshold. For the purposes of the measurements for this graph, the voltage continue to be increased to illustrate the effect of increasing voltage on current. However, in a practical implementation of the measurement apparatus 1, the increase in voltage would be stopped when the sample of current exceeded the threshold of the first category (“fail”).

In each of FIGS. 4-7, a line is shown for a function relating each category of threshold to voltage for the last iteration of calculation of thresholds. The functions relating the threshold of the first category to voltage 20, 28, 36, 44, the functions relating threshold of the second category to voltage 22, 30, 38, 46 and the functions relating threshold of the third category to voltage 21, 29, 37, 45 are shown. If any of the previous samples exceed the threshold for that voltage indicated by the illustrated function, which is recalculated for each interaction, then the respective threshold may be deemed to have been crossed.

The processing of the samples to generate the respective thresholds comprises, in an example, curve fitting by linear regression, statistical evaluation of noise by calculating standard deviation of the samples, generating a running average for each iteration of slope and intercept of the fitted curve (which may be a straight line), suppression of negative slopes and intercepts, and analysis of each data point, that is to say sample, versus calculated limits. Curve fitting may be by non-linear regression in an example.

There are several coefficients in the algorithm for determining the respective thresholds which once pre-determined, can be left unchanged for the operation of the measurement apparatus on vastly different motors under tests. The method is intended to be applied to testing rotating machines, but it can be applied to any system which requires the SV or RV tests.

The algorithm performs calculations after each step (or measured point), or as the data becomes available. This is kind of on-the-fly processing, in which the last point of the data is evaluated versus all the points acquired so far, and because of that the algorithm adapts itself to whatever data is gathered. The evaluation is made against limits which are calculated in relation to the real data. The limits are re-evaluated at each step so that the changing character of the curve can be taken into account, such as the pre-polarisation effects mentioned above.

More than one limit can be generated, so rather than having just pass/fail evaluation, there can be more gradual assessment such as: pass, caution, warning, fail and any other number of such limits, also numerical or percentage, e.g. 90% probability of fail.

An example of a graphical display is shown in FIGS. 4-7. The example shows 3 limits, which produce 4 ranges. This makes the diagnosis of the state of insulation more granular. The “pass” is for all the points below the threshold of the second category.

A motor which is diagnosed as “caution” will very likely continue to run for some time, but a more regular diagnostics might need to be scheduled in order to detect possible further deterioration. A motor with “warning” can continue to be run, but an immediate overhaul should be planned. A “fail” requires immediate disassembly due to risk of catastrophic failure during operation. A “pass” allows further uninterrupted work. This method gives a defined way of how the damage to insulation can be prevented, quantified by the test data itself, without the need to prior interaction from the user to set the limits, thus avoiding operator errors.

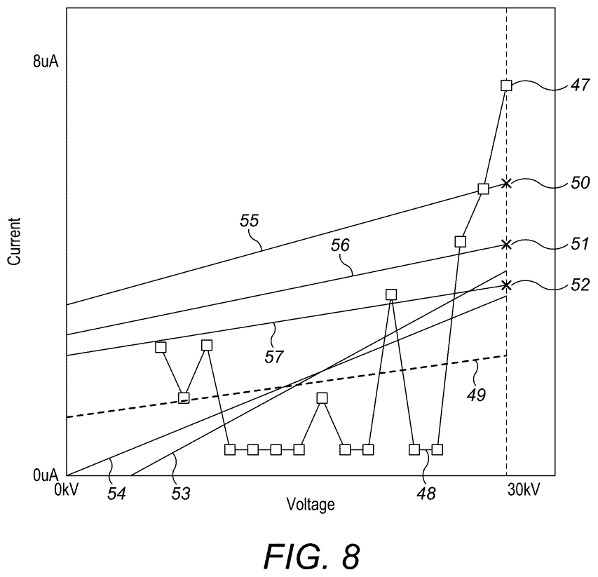

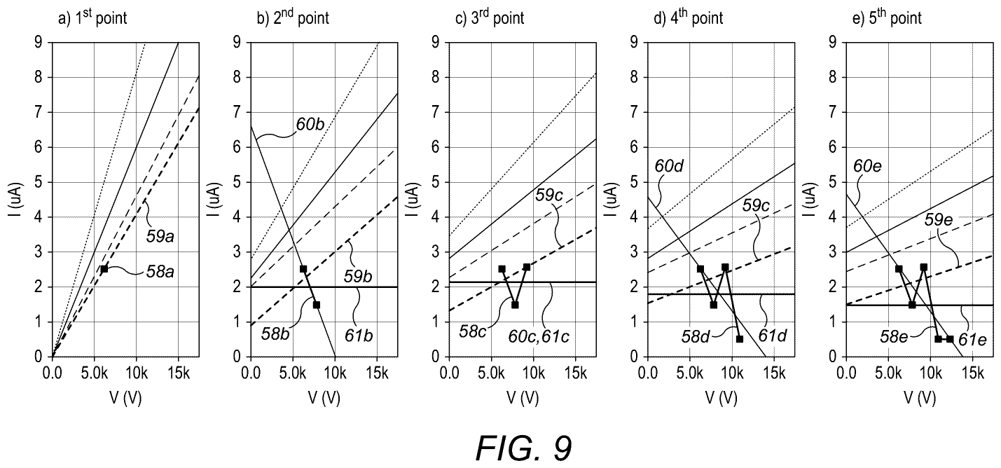

FIG. 8 is a graph illustrating samples of measured current as a function of applied voltage and thresholds of a first, second and third category for a fifth set of measurements, illustrating fitting of a function to the measured samples. FIG. 9 shows a time sequence of measurements a) to e) illustrating how the thresholds of a first, second and third category are generated.

FIG. 8 shows a series of samples of current 48, plotted as a function of applied voltage. The last sample 47 taken for the iteration illustrated is shown. The threshold of the first category 50, second category 52 and third category 51 are shown for the sample 47 taken in the iteration illustrated. Also, lines are shown 55, 57, 56 for the respective thresholds as a function of voltage. Also shown is a function 49 which relates current to voltage to at least one sample measured for the respective iteration and for samples measured for a plurality of previous iterations. The function 49 may be referred to as a base line or base line function. In an example, the base line function may be a non-linear curve, which may be derived by non-linear regression.

The respective thresholds for the current measured in each iteration are determined by a process comprising, for each iteration, fitting the base line function 49 which relates current to voltage to at least one sample measured for the respective iteration and for samples measured for a plurality of previous iterations. The fitting comprises calculating a mean gradient of the base line function for the current iteration and previous iterations, in which, dependent on a respective gradient being negative, the respective gradient is set to zero for the purpose of calculating the mean gradient. The fitting also comprises calculating a mean intercept of the function for the current iteration and previous iterations, in which, dependent on a respective intercept being negative, the respective intercept is set to zero for the purpose of calculating the mean intercept. As mentioned previously, the samples representing current may be expressed in terms of insulation resistance, which is directly related to current, being the applied voltage divided by the current. If the base line function is expressed in terms of a resistance value as a function of applied voltage, rather than current as a function of applied voltage, then the calculation of the baseline may be performed by applying equivalent rules that would produce an equivalent threshold in terms of resistance to that produced in terms of current.

The respective thresholds for the current measured in the iteration are calculated by a process comprising determining a value of the function for the value of voltage applied for the iteration in question and multiplying the determined value of the function by a first predetermined factor. The respective thresholds for the current measured in the iteration are calculated by a process comprising taking the determined value of the function multiplied by the predetermined factor and adding a factor related to a noise level in the measured data. The factor related to a noise level in the measured data is generated by a process comprising taking a standard deviation of the difference between measured data and the function, in which more recent data is de-weighted in comparison to older data. Line 53 shows a fit to the samples of 48 by linear regression, and line 54 shows a corrected regression line to remove a negative intercept. The running average of the corrected regression lines for each iteration is used to calculate the base line function 49, from which the respective thresholds for the iteration are calculated. This will be explained in connection with the time sequence illustrated by FIG. 9a) to 9e).

FIGS. 9a), 9b), 9c), 9d) and 9e) show a time sequence of measurements illustrating an example of the steps of how the thresholds of a first, second and third category are generated.

There are several coefficients factors to be pre-determined, which may be referred to as follows:
noise—multiplier of noise
bad—multiplier for bad limit
suspect—multiplier for suspect limit
good—multiplier for good limit

As shown in FIG. 9a), when the first sample 58a is acquired, base line 59a is set which goes from the origin (V=0, I=0) to this point. A slope and intercept (y=slope*x+intercept) is derived for this line, such that intercept=0V, slope=I/V of the measured point. The noise is assumed to be zero at this step. For each iteration, that is to say for each step in the time sequence, for example as shown in FIGS. 9a), 9b), 9c) and 9e), three thresholds are produced by multiplying the equation for the base line, as represented by the slope of the base line (“slope_avg”) and the intercept of the base line (“intercept_avg”) by the factors as listed above, namely:

$$GOOD [ ] = ( VOLTAGE [ ] * slope\_avg + intercept\_avg ) * good + stdev * noise$$

$$SUSPECT [ ] = ( VOLTAGE [ ] * slope\_avg + intercept\_avg ) * suspect + stdev * noise$$

$$BAD [ ] = ( VOLTAGE [ ] * slope\_avg + intercept\_avg ) * bad + stdev * noise$$

As shown in FIG. 9b), for the sample, a linear regression 60b can be calculated for the first and second samples 58b. If either the slope or the intercept is negative, then they have to be “corrected” so that negative values are suppressed. This is because negative values represent non-physical behaviour. In the case shown in FIG. 9b, the intercept is positive and the slope is negative. Therefore, the slope is forced to zero and the intercept is calculated as the average of both points acquired so far. This produces the solid grey horizontal line 61b.

The new base line 59b is calculated such that there is a running average of slope values, and running average of intercept values from this 59b and from all previous iterations 59a. Therefore, the new base has a shallower slope than for the previous iteration.

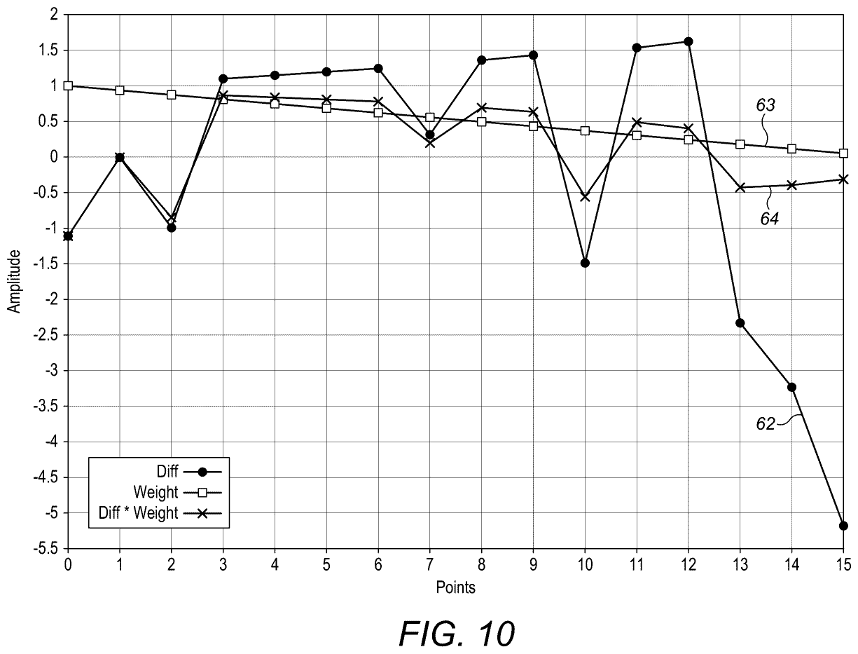

FIG. 10 illustrates how the measure of noise, as used to generate the thresholds, is calculated in an example. As shown on FIG. 10, the base line is subtracted from the samples to produce a difference (diff). This is shown in FIG. 10 as line 62. Additionally, a corresponding set of weights is generated such that, in an example, they start at 1 for the first point and end up close to zero, or zero, for the last available point. This is shown in FIG. 10 as line 63. The differences are multiplied by the weights, so that the high differences for the last points are effectively suppressed. This ensures that a genuine measurement noise which is likely to be similar throughout the test is taken into account for the initial points, but it is not affected by the high differences if the current start accelerating to high values, typically for the last point. The weighted difference data is shown in FIG. 10 as line 64. A standard deviation (stdev value) is calculated for this weighted difference data 64. The standard deviation is a measure of the level of noise. In an alternative example, a variance may be taken as the measure of noise.

Returning to the sequence of FIGS. 9a) to 9e), in this example, the three limits, “GOOD”, “BAD” and “SUSPECT”, that is to say the thresholds of the second, first and third categories respectively, are produced for each iteration, using the measure of standard deviation, stdev, calculated as described in connection with FIG. 10.

As shown in FIG. 9b), because in this case the stdev is significant, the limit for “good” (this would indicate “caution” of passed) is spaced farther away from the base line than it was the case for the 1st point as shown in FIG. 9a).

For each iteration, once the limits, that is to say thresholds, are defined then the last point, that is to say the sample for the present iteration, and in an example any previous samples, can be now checked against those limits in order to produce diagnosis of the state of insulation. If the present sample is below the threshold of a second category, this indicates pass, between the thresholds of the second and third categories indicates caution, between the thresholds of the third category and first category indicates warning, and above the threshold of the first category indicates fail.

If the result is pass/caution/warning the test will progress to the next point, namely, the processor will request from the hardware another step of the test, that is to say an increase in voltage. Once a “fail” is detected then the processor can stop the hardware from applying increased voltage and risking permanent damage to the insulation. In an example, the automatic stop function may be enabled or disabled by an operator.

For the 3rd sample, and all the following samples, as illustrated in FIGS. 9a) to 9e), the same algorithm repeats: fit the curve by linear regression to all previous data, correct slope and intercept if necessary, calculate running average of slope and intercept to produce base, calculate difference between new base and real data, apply weights to the difference data, calculate stdev of difference between base and real data, calculate limits based on the running average of slope and intercept and the stdev, check the point(s) against the limits to give diagnosis. The sequence is repeated for each step.

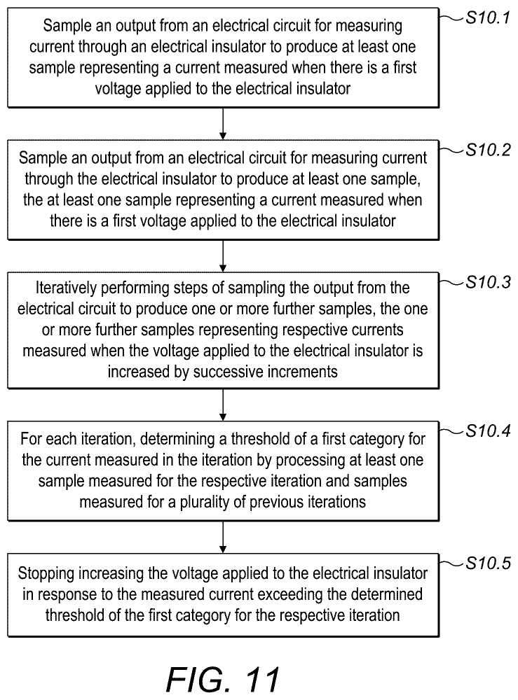

FIG. 11 is a flow chart illustrating a method of operation of the measurement apparatus according to steps S10.1 to S 10.5.

As mentioned already, the measurement equipment may comprise one or more processors for causing the equipment to perform the methods as described. The one or more processors may comprise, or be in communication with, a computer-readable storage medium, such as a memory chip or other data storage device. At least one of the one or more processors may be situated within a user device, such as a smart phone, connected to a meter comprising a circuit for measuring current. The computer-readable storage medium may hold instructions for causing one or more processors to cause the measurement apparatus to receive at least one sample, the at least one sample representing a current measured when there is a first voltage applied to the electrical insulator and iteratively perform steps of receiving one or more further samples, the one or more further samples representing respective currents measured when the voltage applied to the electrical insulator is increased by successive increments. The samples may be received by the user device from the meter. The instructions may cause the measurement apparatus to, for each iteration, determine a threshold of a first category for the at least one sample representing current measured in the iteration by processing at least one sample measured for the respective iteration and samples measured for a plurality of previous iterations; and cause the measurement apparatus to stop increasing the voltage applied to the electrical insulator in response to the measured at least one sample representing current exceeding the determined threshold of the first category for the respective iteration. The instructions may cause one or more processors to cause the measurement apparatus to sample an output from an electrical circuit for measuring the electrical parameter for the electrical insulator to produce at least one sample and send the sample to at least one of the one or more processors and

sample the output from the electrical circuit to produce one or more further samples representing respective currents measured when the voltage applied to the electrical insulator is increased by successive increments and send the one or more further samples to at least one of the one or more processors. Sending the samples may be by a wired connection, or by a radio link such as Bluetooth or WiFi, or by any other method. Parts of the instructions may be performed by a processor at the meter and parts of the instructions may be performed by a processor at the user device.

The above embodiments are to be understood as illustrative examples of the invention. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. A method of operation of a measurement apparatus for performing a measurement of insulation resistance of an electrical insulator by applying a voltage to the electrical insulator, increasing the voltage with time, and measuring the resulting current through the electrical insulator for a plurality of applied voltages, the method comprising:
sampling an output from an electrical circuit for measuring current through the electrical insulator to produce at least one sample, the at least one sample representing a current measured when there is a first voltage applied to the electrical insulator;
iteratively performing steps of sampling the output from the electrical circuit to produce one or more further samples, the one or more further samples representing respective currents measured when the voltage applied to the electrical insulator is increased by successive increments;
for each iteration, determining a threshold of a first category for the at least one sample representing current measured in the iteration by processing at least one sample measured for the respective iteration and samples measured for a plurality of previous iterations; and
stopping increasing the voltage applied to the electrical insulator in response to the at least one sample representing current measured in the iteration exceeding the determined threshold of the first category for the respective iteration.

2. The method of claim 1, comprising determining the threshold of the first category for the at least one sample representing current measured in each iteration by a process comprising, for each iteration, fitting a function which relates current to voltage to at least one sample measured for the respective iteration and for samples measured for a plurality of previous iterations.

3. The method of claim 2, wherein said fitting comprises calculating a mean gradient of the function for the current iteration and previous iterations, in which, dependent on a respective gradient being negative, the respective gradient is set to zero for the purpose of calculating the mean gradient.

4. The method of claim 3, wherein said fitting comprises calculating a mean intercept of the function for the current iteration and previous iterations, in which, dependent on a respective intercept being negative, the respective intercept is set to zero for the purpose of calculating the mean intercept.

5. The method of claim 1, comprising calculating the threshold of a first category for the at least one sample representing current measured in the iteration by a process comprising determining a value of the function for the value of voltage applied for the iteration in question and multiplying the determined value of the function by a first predetermined factor.

6. The method of claim 5 comprising calculating the threshold of a first category for the at least one sample representing current measured in the iteration by a process comprising taking the determined value of the function multiplied by the predetermined factor and adding a factor related to a noise level in the measured data.

7. The method of claim 6, wherein the factor related to a noise level in the measured data is generated by a process comprising taking a standard deviation or variance of the difference between measured data and the function, in which more recent data is de-weighted in comparison to older data.

8. The method of claim 1, comprising generating an electronic display showing measured samples of current as a function of applied voltage and a function representing a threshold of the first category as a function of applied voltage.

9. The method of claim 1, comprising:
determining a threshold of a second category for each iteration by processing at least one sample measured for the respective iteration and samples measured for a plurality of previous iterations; and
generating a second electronic signal indicating that there is a risk of insulation failure in response to the measured at least one sample representing current exceeding the determined threshold of the second category for the respective iteration.

10. The method of claim 9, comprising generating an electronic display showing measured samples of current as a function of applied voltage and the threshold of the second category as a function of applied voltage.

11. The method of claim 9, comprising:
determining a threshold of a third category for each iteration by processing at least one sample measured for the respective iteration and samples measured for a plurality of previous iterations; and
generating a third electronic signal indicating that there is a risk of insulation failure in response to the measured at least one sample representing current exceeding the determined threshold of the third category for the respective iteration, wherein the third electronic signal indicates a higher risk of insulation failure than does the second electronic signal.

12. The method of claim 1, comprising stopping applying voltage to the electrical insulator in response to the measured at least one sample representing current exceeding the determined threshold of the first category for the respective iteration.

13. The method of claim 12, comprising generating an electronic signal indicating that the measurement has stopped in response to the measured at least one sample representing current exceeding the determined threshold of the first category for the respective iteration.

14. Measurement apparatus for performing a measurement of insulation resistance of an electrical insulator by applying a voltage to the electrical insulator, increasing the voltage with time, and measuring the resulting current through the electrical insulator for a plurality of applied voltages, the apparatus comprising:
an electrical circuit for applying a voltage to the electrical insulator;
an electrical circuit for measuring current through the electrical insulator; and
at least one processor configured to cause the measurement apparatus to:
sample an output from an electrical circuit for measuring current through the electrical insulator to produce at least one sample, the at least one sample representing a current measured when there is a first voltage applied to the electrical insulator;
iteratively perform steps of sampling the output from the electrical circuit to produce one or more further samples, the one or more further samples representing respective currents measured when the voltage applied to the electrical insulator is increased by successive increments;
for each iteration, determine a threshold of a first category for the at least one sample representing current measured in the iteration by processing at least one sample measured for the respective iteration and samples measured for a plurality of previous iterations; and
stop increasing the voltage applied to the electrical insulator in response to the measured at least one sample representing current exceeding the determined threshold of the first category for the respective iteration.

15. The measurement apparatus of claim 14 wherein the at least one processor is configured to cause the measurement apparatus to determine the threshold of the first category for the at least one sample representing current measured in each iteration by a process comprising, for each iteration, fitting a function which relates current to voltage to at least one sample measured for the respective iteration and for samples measured for a plurality of previous iterations.

16. The measurement apparatus of claim 15, wherein the measurement apparatus comprises a meter and a device external to the meter comprising a processor and a display, wherein the meter comprises the electrical circuit for applying a voltage to the electrical insulator, the electrical circuit for measuring current through the electrical insulator and an electrical circuit for communicating with said device.

17. A computer-readable storage medium holding instructions for causing one or more processors to cause measurement apparatus for performing a measurement of insulation resistance of an electrical insulator to:
receive at least one sample, the at least one sample representing a current measured when there is a first voltage applied to the electrical insulator;
iteratively perform steps of receiving one or more further samples, the one or more further samples representing respective currents measured when the voltage applied to the electrical insulator is increased by successive increments;
for each iteration, determine a threshold of a first category for the at least one sample representing current measured in the iteration by processing at least one sample measured for the respective iteration and samples measured for a plurality of previous iterations; and
cause the measurement apparatus to stop increasing the voltage applied to the electrical insulator in response to the measured at least one sample representing current exceeding the determined threshold of the first category for the respective iteration.

18. The computer-readable storage medium of claim 17, holding instructions for causing one or more processors to cause the measurement apparatus to:
sample an output from an electrical circuit for measuring the electrical parameter for the electrical insulator to produce at least one sample and send the sample to at least one of the one or more processors; and
sample the output from the electrical circuit to produce one or more further samples representing respective currents measured when the voltage applied to the electrical insulator is increased by successive increments and send the one or more further samples to at least one of the one or more processors.
